(19) United States
(12) Patent Application Publication
(10) Pub. No.: US 2026/0269169 A1
(43) Pub. Date: Sep. 10, 2026

(54) SCANNING ELECTRON MICROSCOPE AND SPECIMEN OBSERVATION METHOD

(71) Applicant: Hitachi High-Tech Corporation, Minato-ku, Tokyo (JP)

(72) Inventors: Hiroyasu SHICHI, Tokyo (JP); Nobuhiro OKAI, Tokyo (JP); Naomasa SUZUKI, Tokyo (JP); Tetsuya NIIBORI, Tokyo (JP); Eri SAITO, Tokyo (JP); Takashi SATO, Tokyo (JP)

(21) Appl. No.: 18/868,908

(22) PCT Filed: Jun. 10, 2022
(86) PCT No.: PCT/JP2022/023427

§ 371 Date: Nov. 25, 2024

(51) Int. Cl. H01J 37/147; H01J 37/244; H01J 37/26; H01J 37/28

(52) U.S. Cl. CPC H01J 37/1477; H01J 37/244; H01J 37/265; H01J 37/28; H01J 2237/24465; H01J 2237/2448; H01J 2237/2449; H01J 2237/281

(57) ABSTRACT

Provided is a deflector including an electron conversion electrode 141 provided to collide with a secondary electron emitted from a specimen due to emission of a primary electron beam, a first electrode 142 and a second electrode 143 facing each other and allowing transmission of an electron therethrough, and a third electrode 144 facing the first electrode with the second electrode interposed therebetween, the electron conversion electrode is segmented into a plurality of segmented electrodes, and a potential of the third electrode has a positive potential difference relative to a potential of the second electrode.

### TECHNICAL FIELD

The present invention relates to a scanning electron microscope and a specimen observation method using the same.

### BACKGROUND ART

An electron microscope is an apparatus for observing a surface or inside of a specimen in an enlarged manner by emitting an electron beam. In particular, in a scanning electron microscope, an electron microscope image is obtained by scanning the electron beam and using a secondary electron or a reflected electron emitted from the specimen as a brightness signal.

The scanning electron microscope is used as an indispensable apparatus at a site of development, manufacturing, and analysis of a semiconductor device. In recent years, semiconductor devices have become highly miniaturized and three-dimensional. Therefore, there is an increasing need to observe a high-aspect-ratio trench portion using the scanning electron microscope.

It is known that shape contrast or shading contrast of an electron microscope image is improved by providing an electron microscope with an angle discrimination function and detecting a signal electron according to an emission angle. For example, PTL 1 discloses a scanning electron microscope including a metal plate that has segmented areas to which voltages can be independently applied and that generates a tertiary electron by causing collision of secondary electrons or reflected electrons.

### CITATION LIST

### Patent Literature

PTL 1: JP2012-3909A

### SUMMARY OF INVENTION

### Technical Problem

Since most of secondary electrons generated from a bottom of a trench collide with a side wall of the trench and are lost, the number of detectable secondary electrons escaping to the outside of the trench is small. Meanwhile, most of the secondary electrons emitted from sides of the trench (trench top) are detectable. Therefore, with the scanning electron microscope, when the trench is observed, the bottom of the trench is observed dark.

In order to observe a trench bottom of a trench portion having a high aspect ratio, it is sufficient if the number of secondary electrons detected from a trench top is reduced without reducing the number of secondary electrons detected from the trench bottom. That is, it is sufficient if a ratio of the number of secondary electrons detected from the trench bottom (B) to the number of secondary electrons detected from the trench top (T), that is, a BT ratio is increased. For this purpose, it is sufficient if detection is performed while limiting an emission angle of the secondary electrons.

If a secondary electron signal from the trench top is not sufficiently low as compared to a secondary electron signal from the trench bottom, it is difficult to measure a dimension of a microstructure of the trench bottom or observe foreign matter, and PTL 1 does not give sufficient consideration to reducing the secondary electron signal from the trench top in order to improve visibility of the trench bottom.

An object of the invention is to provide a scanning electron microscope suitable for measuring a dimension of a microstructure of a trench bottom and observing foreign matter even at a trench portion having a high aspect ratio.

### Solution to Problem

A scanning electron microscope according to an embodiment of the invention includes: an electron source; an objective lens configured to focus a primary electron beam emitted from the electron source on a specimen; a deflector configured to deflect, using at least an electric field, an electron between the electron source and the objective lens; a stage where the specimen is placed; a power supply configured to apply, to the stage, a voltage for decelerating the primary electron beam; a detector configured to detect an electron; and a control apparatus, in which the deflector includes an electron conversion electrode provided to collide with a secondary electron emitted from the specimen due to emission of the primary electron beam, a first electrode and a second electrode facing each other and allowing transmission of an electron therethrough, and a third electrode facing the first electrode with the second electrode interposed therebetween, the detector detects a tertiary electron that is emitted due to collision of the secondary electron emitted from the specimen with the electron conversion electrode and that is transmitted through the first electrode, the electron conversion electrode is segmented into a plurality of segmented electrodes, and the control apparatus causes a potential of the third electrode to have a positive potential difference relative to a potential of the second electrode.

### Advantageous Effects of Invention

Provided is a scanning electron microscope suitable for measuring a dimension of a microstructure of a trench bottom and observing foreign matter.

Other problems and novel features will become apparent from description of the present specification and the accompanying drawings.

### BRIEF DESCRIPTION OF DRAWINGS

FIG. 1 shows an example of an overall configuration of an electron microscope.

FIG. 2 shows a secondary electron emission vector emitted from a trench.

FIG. 3A is a cross-sectional view of a Wien filter in a first embodiment as viewed from beside.

FIG. 3B is a cross-sectional view of the Wien filter in the first embodiment as viewed in a planar direction.

FIG. 4 schematically shows how secondary electrons are emitted from a trench bottom and a trench top.

FIG. 5A shows collision positions of secondary electrons with an electron conversion electrode.

FIG. 5B shows collision positions of secondary electrons with the electron conversion electrode.

FIG. 6A shows collision positions of secondary electrons with the electron conversion electrode.

FIG. 6B shows collision positions of secondary electrons with the electron conversion electrode.

FIG. 7A shows behaviors of a secondary electron, a reflected electron, and a tertiary electron in the first embodiment.

FIG. 7B shows behaviors of a secondary electron, a reflected electron, and a tertiary electron in the first embodiment.

FIG. 8A is a cross-sectional view of a Wien filter in a second embodiment as viewed from beside.

FIG. 8B is a cross-sectional view of the Wien filter in the second embodiment as viewed in a planar direction.

FIG. 9A shows behaviors of a secondary electron, a reflected electron, and a tertiary electron in the second embodiment.

FIG. 9B shows behaviors of a secondary electron, a reflected electron, and a tertiary electron in the second embodiment.

FIG. 10A shows collision positions of secondary electrons with a beam guide and an electron conversion electrode.

FIG. 10B shows collision positions of secondary electrons with the beam guide and the electron conversion electrode.

FIG. 11A shows collision positions of secondary electrons with the beam guide and the electron conversion electrode.

FIG. 11B shows collision positions of secondary electrons with the beam guide and the electron conversion electrode.

FIG. 12A is a cross-sectional view of an electron deflector in a third embodiment as viewed from beside.

FIG. 12B is a cross-sectional view of the electron deflector according to the third embodiment as viewed in a planar direction.

FIG. 13A shows behaviors of a secondary electron, a reflected electron, and a tertiary electron in the third embodiment.

FIG. 13B shows behaviors of a secondary electron, a reflected electron, and a tertiary electron in the third embodiment.

FIG. 14A shows collision positions of secondary electrons with a beam guide and an electron conversion electrode.

FIG. 14B shows collision positions of secondary electrons with the beam guide and the electron conversion electrode.

FIG. 15A is a cross-sectional view of a Wien filter in a fourth embodiment as viewed from beside.

FIG. 15B is a cross-sectional view of the Wien filter in the fourth embodiment as viewed in a planar direction.

FIG. 16 shows a detailed structure of a beam guide and an electron conversion electrode in the fourth embodiment.

FIG. 17A shows behaviors of a secondary electron, a reflected electron, and a tertiary electron in the fourth embodiment.

FIG. 17B shows behaviors of a secondary electron, a reflected electron, and a tertiary electron in the fourth embodiment.

FIG. 18A shows collision positions of secondary electrons with the beam guide and the electron conversion electrode.

FIG. 18B shows collision positions of secondary electrons with the beam guide and the electron conversion electrode.

FIG. 19A shows collision positions of secondary electrons with the beam guide and the electron conversion electrode.

FIG. 19B shows collision positions of secondary electrons with the beam guide and the electron conversion electrode.

FIG. 20 shows an example of a screen displayed on a display of a scanning electron microscope.

### DESCRIPTION OF EMBODIMENTS

Hereinafter, embodiments of an electron microscope according to the invention will be described with reference to the accompanying drawings. The electron microscope is an apparatus for observing a specimen by emitting an electron beam to the specimen.

### First Embodiment

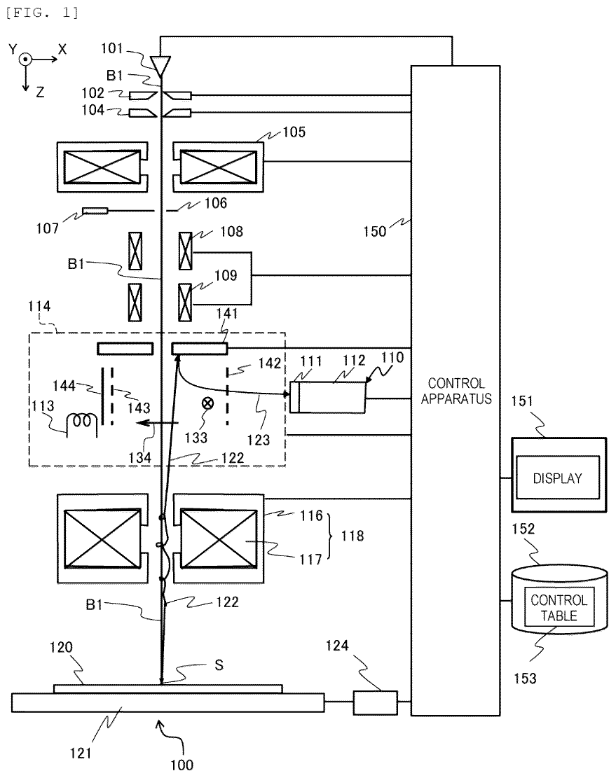

An overall configuration of an electron microscope 100 according to a first embodiment will be described with reference to FIG. 1. A vertical direction is referred to as a Z-direction, and horizontal directions are referred to as an X-direction and a Y-direction. The electron microscope 100 includes, as main components, an electron gun 101, an extraction electrode 102, an anode 104, a focusing lens 105, an aperture 106, an adjustment knob 107, an upper deflector 108, a lower deflector 109, a detector 110, a Wien filter 114, an objective lens 118, a specimen stage 121, a power supply 124 that applies a voltage to the specimen stage, a control apparatus 150, a display 151, and a storage apparatus 152. The control apparatus 150 is an apparatus that controls an operation of each unit, and is, for example, a computer. The storage apparatus 152 stores a control table 153 that defines control conditions such as a voltage and a current of each unit. The control apparatus 150 reads the control table 153 from the storage apparatus 152 and controls each unit based on the control conditions defined in the control table 153.

The electron gun 101 is an electron source that emits electrons, and is, for example, a field emission cathode. A negative voltage of, for example, 4,000 V is applied to the electron source. The extraction electrode 102 and the anode 104 are electrodes to which a positive voltage relative to the electron gun 101 is applied, and each has a hole through which a primary electron beam B1, which is electrons emitted from the electron gun 101, passes. An absolute value of the voltage of the anode 104 relative to the electron gun 101 is larger than that of the extraction electrode 102. The focusing lens 105 is a lens that focuses the primary electron beam B1. The aperture 106 is a member that determines an angular spread of the primary electron beam B1 at the objective lens 118, and has a hole through which the primary electron beam B1 passes. The adjustment knob 107 is used to adjust a center position of the aperture 106. The upper deflector 108 and the lower deflector 109 deflect the primary electron beam B1 to scan over the specimen 120.

The objective lens 118 is a lens that focuses the deflected primary electron beam B1, and includes a magnetic pole 116 having a rotationally symmetrical shape and an objective lens coil 117. A magnetic field generated by a current flowing through the objective lens coil 117 narrows the primary electron beam B1.

The specimen stage 121 holds the specimen 120 and controls a position and a posture of the specimen 120. That is, the specimen stage 121 moves the specimen 120 in the horizontal direction or the vertical direction, or rotates the specimen 120 in the vertical direction serving as a rotation axis. The power supply 124 that applies the voltage to the specimen stage is connected to the specimen stage 121, and for example, a negative voltage of 3,000 V is applied to form an electric field that decelerates the primary electron beam B1 between the specimen 120 on the specimen stage 121 and the objective lens 118 (retarding method).

When the decelerated primary electron beam B1 is emitted to a point S on the specimen 120, secondary electrons and reflected electrons (backscattered electrons) are emitted from the point S. The secondary electrons and the reflected electrons have different generation mechanisms, the secondary electrons are electrons excited from atoms constituting the specimen by inelastic scattering of primary electrons in the specimen, and the reflected electrons are electrons backscattered in a process of scattering of the emitted primary electrons. Therefore, each secondary electron is, for example, an electron having energy of less than 100 eV, and each reflected electron is, for example, an electron having energy of 100 eV or more.

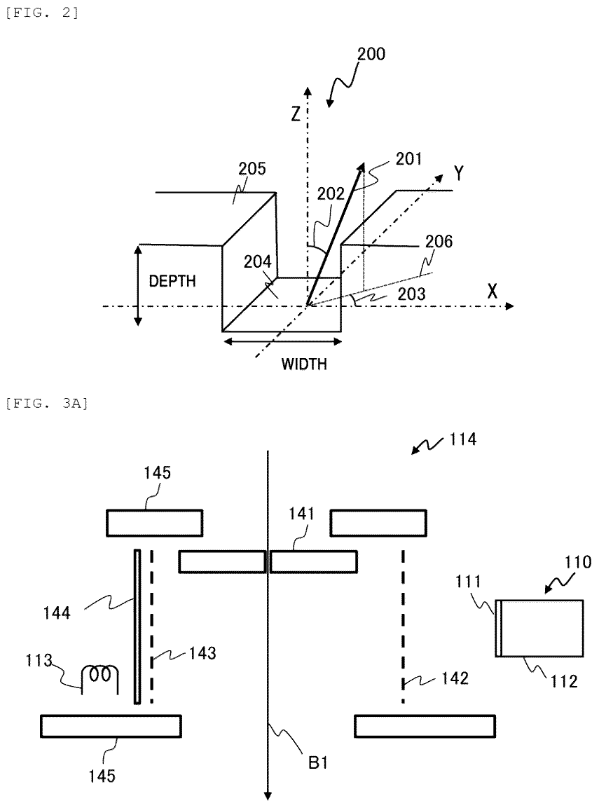

FIG. 2 shows a secondary electron emission vector 201 emitted from a trench 200. FIG. 2 also shows definitions of an elevation angle 202 and an azimuth angle 203 of a secondary electron. The elevation angle 202 is an angle measured from a Z-axis of the secondary electron emission vector 201, and the azimuth angle 203 is an angle measured from an X-axis of a line segment 206 obtained by projecting the secondary electron emission vector 201 onto an XY plane. Secondary electrons are emitted with a distribution approximated by a cosine function with respect to the elevation angle and with an isotropic distribution with respect to the azimuth angle.

Returning to the description of FIG. 1. The electric field that decelerates the primary electron beam B1 also accelerates a secondary electron 122 and lifts the secondary electron 122 into a path of the objective lens 118. The secondary electron 122 lifted into the path is influenced by the magnetic field of the objective lens 118, travels along a helical trajectory toward the electron gun 101, and reaches the Wien filter 114.

A detailed structure of the Wien filter 114 and secondary electron discrimination will be described later, and a principle of secondary electron image generation will be described here. The secondary electron 122 that reaches the Wien filter 114 collides with the electron conversion electrode 141 above. When the secondary electron 122 collides with the electron conversion electrode 141, a tertiary electron 123 is emitted from the electron conversion electrode 141. Although the tertiary electron 123 is a secondary electron in terms of a generation mechanism, here, in order to avoid confusion with the secondary electron emitted from the specimen 120, a secondary electron emitted from other than the specimen 120 due to the secondary electron 122 is referred to as a tertiary electron.

When the electron conversion electrode 141 is at a ground potential, the tertiary electron 123 is deflected toward the detector 110 by an electric field 134 and a magnetic field 133 in the Wien filter 114. Although the electric field 134 and the magnetic field 133 also act on the primary electron beam B1, effects of these two fields cancel each other out, and thus the primary electron beam B1 travels straight.

The detector 110 is a detector that detects the tertiary electron 123 deflected by the Wien filter 114, and includes a fluorescent plate 111 and a photomultiplier tube 112. The fluorescent plate 111 is a flat plate that emits light due to incidence of the tertiary electron 123, and is a detection surface of the detector 110. The photomultiplier tube 112 outputs an electrical signal obtained by amplifying photoelectrons generated by light emission of the fluorescent plate 111. That is, the detector 110 transmits, to the control apparatus 150, a detection signal corresponding to an amount of the tertiary electron 123 incident on the fluorescent plate 111. The control apparatus 150 generates a secondary electron image of the specimen based on the received detection signal. The generated secondary electron image is displayed on the display 151 or stored in the storage apparatus 152.

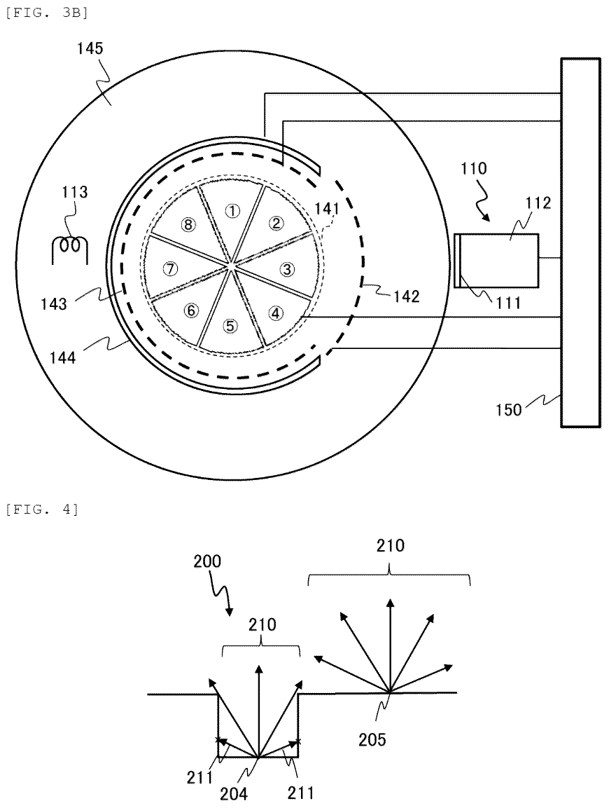

A detailed structure of the Wien filter 114 will be described with reference to FIGS. 3A and 3B. FIG. 3A is a cross-sectional view from beside, and FIG. 3B is a cross-sectional view in a planar direction. The electron conversion electrode 141 with which the secondary electron 122 collides is provided at an upper portion of the Wien filter 114. In the present embodiment, the electron conversion electrode 141 is radially segmented into eight. The segmented electrodes are electrically insulated from each other in order to be independently switched between positive voltage application and negative voltage application or the ground potential, and a separation groove is provided between adjacent electrodes. There is a gap at a center of the electron conversion electrode 141, and the primary electron beam B1 passes therethrough.

The Wien filter 114 includes a first electrode 142, a second electrode 143, a third electrode 144, and a coil 113. The first electrode 142 is an electrode that allows transmission of a tertiary electron generated at the electron conversion electrode 141 therethrough. In order to form an electrode that allows transmission of an electron therethrough, for example, a grid electrode or a mesh electrode may be used. The second electrode 143 and the third electrode 144 face the detector 110, and the third electrode 144 is located outside the second electrode 143. The second electrode 143 is an electrode that allows transmission of an electron reflected due to collision of the secondary electron 122 with the electron conversion electrode 141 therethrough.

A positive 50 V is applied to the first electrode 142, the second electrode 143 is set to the ground potential, and a positive 30 V is applied to the third electrode 144. Further, when a current of about 1 A flows through the coil 113, a magnetic field is generated. As described above, the electric field 134 formed by the first electrode 142 and the second electrode 143 and the magnetic field 133 formed by the coil 113 cancel each other out in terms of an electromagnetic force with respect to the primary electron beam B1. Therefore, the primary electron beam B1 traveling from the electron gun 101 toward the specimen 120 travels straight. Meanwhile, the electric field 134 and the magnetic field 133 act to deflect, toward the detector 110, the tertiary electron 123 emitted from the electron conversion electrode 141.

The Wien filter 114 includes a housing 145 in which electrodes and the like are accommodated and fixed. An insulator, a fixing screw, and the like provided in the housing 145 are not shown.

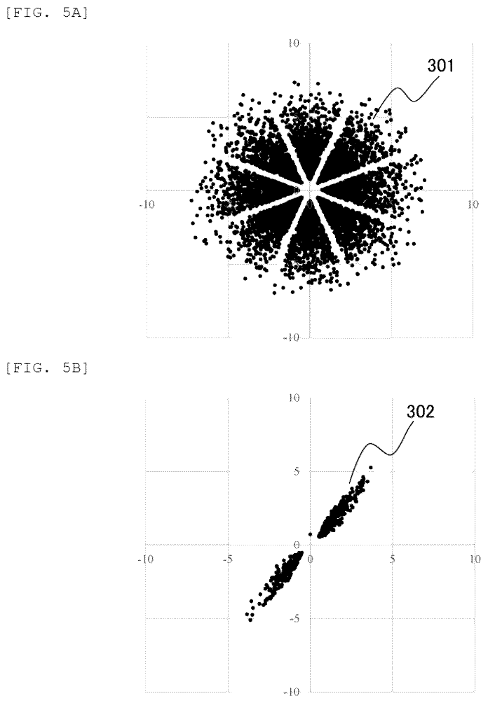

FIG. 4 schematically shows how secondary electrons 210 are emitted from a bottom (trench bottom 204) of the trench 200 and an outer surface (trench top 205) of the trench. Among the secondary electrons 210 emitted from the trench bottom 204, secondary electrons 211 colliding with trench side surfaces are lost and thus are not detected. As a result, the number of secondary electrons emitted from the trench top 205 is larger than the number of secondary electrons emitted from the trench bottom 204. Therefore, in a secondary electron image, the trench top is observed bright and the trench bottom is observed dark. When an aspect ratio of the trench 200 is large, that is, when a trench depth with respect to a trench width is large, the trench bottom is much darker than the trench top, and visibility of a microstructure of the trench bottom and foreign matter deteriorates.

In the present embodiment, the electron conversion electrode 141 of the Wien filter is radially segmented into eight. A power supply is connected to each of segmented electrodes constituting the electron conversion electrode 141, and a part of the segmented electrodes are set to the ground potential or applied with a negative voltage whereas a part of the segmented electrodes are applied with a positive voltage by the control apparatus 150. A tertiary electron emitted from a segmented electrode set to the ground potential or a negative potential is directed to the detector. Meanwhile, a tertiary electron emitted from a segmented electrode to which a positive voltage is applied is pulled back to the electron conversion electrode 141 by the electric field and thus is not detected. Accordingly, it is possible to discriminate a secondary electron detected based on a collision position of the secondary electron with the electron conversion electrode 141.

Here, the inventor focuses on a trajectory of the secondary electron 122 emitted from the specimen 120. If an energy distribution, an emission elevation angle distribution, an emission azimuth angle distribution, and the like of the secondary electron are assumed, an electron trajectory from the specimen 120 to the electron conversion electrode 141 of the Wien filter 114 can be obtained. Therefore, a collision position of the secondary electron 122 on the electron conversion electrode 141 can be obtained.

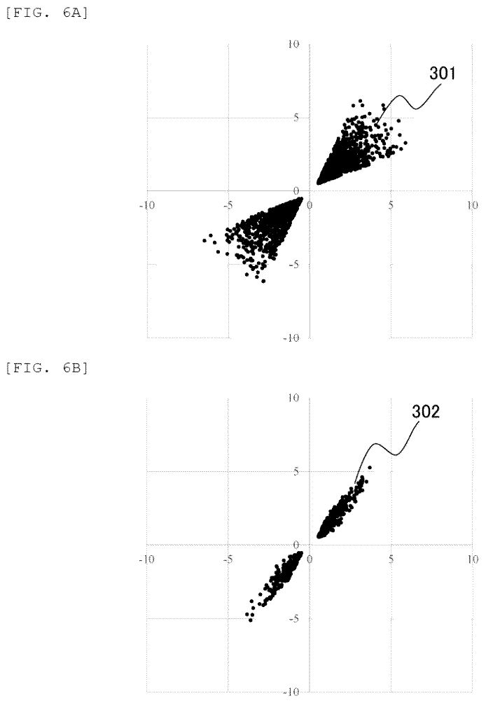

FIG. 5A shows collision positions 301 of secondary electrons with the electron conversion electrode when 10,000 secondary electrons are emitted from the trench top. It is found that the collision positions of the secondary electrons from the trench top spread concentrically from the center of the electron conversion electrode. Radially extending areas in which collision of secondary electrons is not observed correspond to separation grooves between the segmented electrodes. The secondary electrons displayed in FIG. 5A are secondary electrons that can be detected by the detector 110, and the number of secondary electrons colliding with the electron conversion electrode is about 6,500 when counted.

FIG. 5B shows collision positions 302 of secondary electrons with the electron conversion electrode in a case where 10,000 secondary electrons are emitted from the trench bottom when an aspect ratio of the trench is 5. It is found that the collision positions of the secondary electrons from the trench bottom are distributed in an elongated elliptical shape. A major axis direction of the ellipse is inclined by about 40° clockwise from a Y-axis. This is because each secondary electron 122 is subjected to a rotational effect due to the magnetic field of the objective lens 118. The number of secondary electrons colliding with the electron conversion electrode is about 500. Therefore, a ratio of the number of 500 secondary electrons emitted from the trench bottom to the number of 6,500 detected secondary electrons emitted from the trench top, that is, a BT ratio, is about 0.08.

Electron conversion electrodes with a large proportion of the secondary electrons colliding from the trench bottom are a segmented electrode 2 and a segmented electrode 6 of the electron conversion electrode 141 when comparing FIG. 5B with FIG. 3B. Here, the segmented electrodes 2 and 6 of the electron conversion electrode 141 are set to the ground potential, and a positive voltage of 60 V is applied to other six segmented electrodes, that is, segmented electrodes 1, 3, 4, 5, 7, and 8. In this case, the secondary electrons colliding with the segmented electrodes 2 and 6 are detected, whereas secondary electrons colliding with the other six segmented electrodes are not detected. In this way, the electron conversion electrode is radially segmented, the segmented electrodes facing each other are made to have substantially the same potential, and thus an azimuth angle suitable for observing the trench bottom can be discriminated.

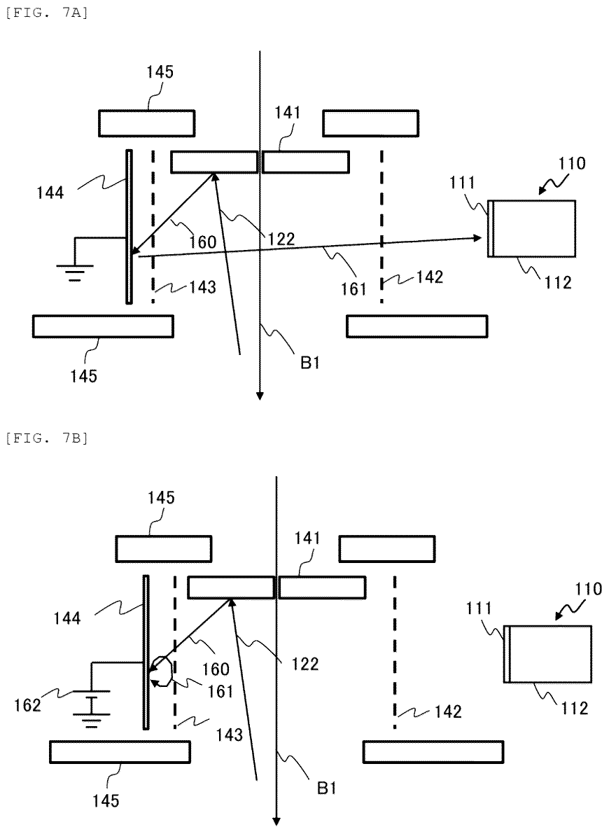

As for secondary electrons that can be detected when only the segmented electrodes 2 and 6 are set to the ground potential, FIG. 6A shows the secondary electrons from the trench top, and FIG. 6B shows the secondary electrons from the trench bottom. FIGS. 6A and 6B respectively show collision positions of the secondary electrons on the segmented electrodes 2 and 6 extracted from FIGS. 5A and 5B. When counted, the number of secondary electrons from the trench top is about ¼ of that before the discrimination, which is about 1,600. Meanwhile, when counted, the number of secondary electrons from the trench bottom is almost the same as that before the discrimination, which is about 500. In this case, the BT ratio is about 0.3. In this way, by discriminating the azimuth angle of the secondary electrons emitted from the specimen, the number of secondary electrons from the trench top detected by the detector 110 decreases, whereas the number of secondary electrons from the trench bottom is substantially the same, and thus the BT ratio can be increased.

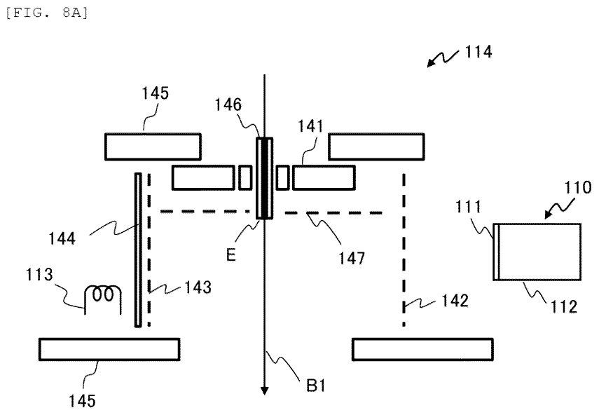

As shown in FIG. 7A, a secondary electron collides with the electron conversion electrode 141 and thus emits a reflected electron 160. Since the secondary electron 122 is accelerated by a retarding voltage, energy of the secondary electron 122 is as high as the voltage applied from the power supply 124 to the specimen 120. Therefore, the reflected electron 160 also has high energy. When the reflected electron 160 passes through the second electrode 143 and collides with the third electrode 144, a tertiary electron 161 is emitted from the third electrode 144. In FIG. 7A, the third electrode 144 is at the ground potential. When the second electrode 143 is also at the ground potential, the tertiary electron 161 emitted from the third electrode 144 passes through the second electrode 143 and further the first electrode 142, and reaches the detector 110.

As described above, by applying a positive voltage to the electron conversion electrode 141, the tertiary electron emitted due to collision of the secondary electron 122 with the electron conversion electrode 141 returns to the electron conversion electrode 141. Meanwhile, as shown in FIG. 7A, the reflected electron 160 is also emitted due to collision of the secondary electrons 122 with the electron conversion electrode 141, and the reflected electron 160 collides with the third electrode 144 to emit the tertiary electron 161. Here, secondary electrons emitted from the trench bottom hardly collide with a segmented electrode to which a positive voltage is applied whereas a large number of secondary electrons emitted from the trench top collide with the segmented electrode to which the positive voltage is applied.

As a result, even when a detection rate of the secondary electrons emitted from the trench top is decreased by applying the positive voltage to the electron conversion electrode 141, the secondary electrons emitted from the trench top are detected by detecting the tertiary electron 161 generated by collision of the reflected electron 160 with the third electrode 144. This makes the trench top relatively bright and reduces visibility of the trench bottom. In this way, in the case of FIG. 7A, since the tertiary electron 161 originating from the reflected electron 160 is detected, an ideal BT ratio of about 0.3 is not actually obtained.

FIG. 7B shows a case where the second electrode 143 is set to the ground potential and a positive voltage of +30 V is applied to the third electrode 144. A power supply 162 for applying the positive voltage is connected to the third electrode 144. In this case, the secondary electron 122 generated at the specimen collides with the electron conversion electrode 141, the emitted reflected electron 160 collides with the third electrode 144, the generated tertiary electron 161 is pulled back to the third electrode 144 by an electric field between the second electrode 143 at the ground potential and the third electrode 144 to which the positive voltage of +30 V is applied, and is absorbed by the third electrode 144 and lost. Therefore, in a scanning electron microscope image in this case, the BT ratio approaches 0.3. That is, as compared to the case of FIG. 7A, the trench top is relatively dark, and the visibility of the trench bottom is improved.

Accordingly, it is possible to provide a scanning electron microscope that can measure a dimension of a microstructure of the trench bottom and observe foreign matter. In addition, it is possible to obtain an image of a microstructure of the trench bottom or foreign matter in the trench.

The voltage applied to the third electrode 144 is preferably switchable between positive voltage application and negative voltage application or the ground potential. As described above, when a positive voltage is applied to the third electrode 144, the visibility of the trench bottom can be improved. Conversely, when the third electrode 144 is applied with a negative voltage or set to the ground potential, a bright image can be obtained during observation of a specimen surface. In this regard, a positive voltage may be applied to the third electrode 144 constantly. In this case, although the specimen surface is slightly darkened in observation, since a power supply or a switching system is not necessary, a low cost apparatus can be provided.

In the present embodiment, an example is described in which the potential of the segmented electrode of the electron conversion electrode 141 can be independently switched, but for example, a positive voltage may be constantly applied to a specific segmented electrode, and other segmented electrodes may be set to the ground potential. A low cost apparatus suitable for trench observation can be provided without requiring a power supply or a switching system.

### Second Embodiment

In a second embodiment, the electron conversion electrode 141 is segmented concentrically into two. Configurations and functions similar to configurations and functions described in the first embodiment are denoted by the same reference numerals, and description thereof is omitted.

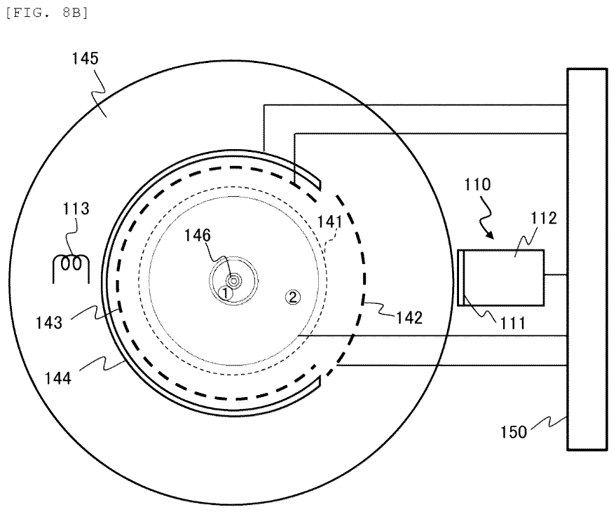

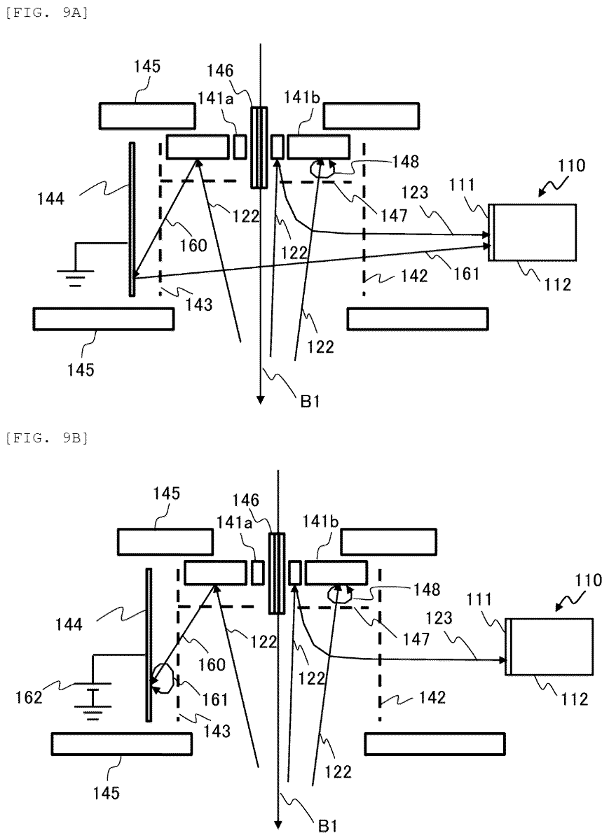

A detailed structure of the Wien filter 114 in the second embodiment will be described with reference to FIGS. 8A and 8B. FIG. 8A is a cross-sectional view from beside, and FIG. 8B is a cross-sectional view in a planar direction. The electron conversion electrode 141 with which the secondary electron 122 collides is provided at the upper portion of the Wien filter 114. In the present embodiment, as shown in FIG. 8B, the electron conversion electrode 141 is segmented concentrically into two. The segmented electrodes are electrically insulated from each other in order to be independently switched between positive voltage application and negative voltage application or the ground potential, and a concentric separation groove is provided between the two electrodes.

Further, in the present embodiment, a beam guide 146 that is a hollow pipe electrode is provided at the center of the electron conversion electrode 141 to penetrate the electron conversion electrode 141, and the primary electron beam B1 passes therethrough. The beam guide 146 and the electron conversion electrode 141 are electrically insulated by the concentric separation groove. The beam guide 146 is at the ground potential and is provided to shield the primary electron beam B1 from an electric field generated by applying a voltage to the electron conversion electrode 141. Accordingly, distortion of the primary electron beam B1 can be reduced. Here, as the beam guide 146, a pipe-like electrode having an annular cross section is shown as an example, but the beam guide 146 may be a cylindrical electrode having a polygonal cross section, and is not limited to be the pipe electrode. It is sufficient that a path made of a conductive material through which the primary electron beam B1 passes is provided. The pipe shape whose cross section is annular is suitable for providing at the center of the electron conversion electrode 141 segmented concentrically. The beam guide is not necessarily at the ground potential, and for example, a low voltage in a range not greatly affecting the primary electron beam may be applied to the beam guide 146.

The Wien filter 114 in the present embodiment includes the first electrode 142, the second electrode 143, and the third electrode 144 similarly to the first embodiment. Since the beam guide 146 is at the ground potential, a tertiary electron is also emitted from an end surface E of the beam guide. That is, the beam guide also serves as an electron conversion electrode. Tertiary electrons emitted from the electron conversion electrode 141 and the end surface E of the beam guide 146 are deflected toward the detector 110 by the electric field formed by the first electrode 142 and the second electrode 143.

In addition to these electrodes, in the present embodiment, a fourth electrode 147 that allows transmission of a secondary electron or a tertiary electron therethrough is provided below the electron conversion electrode 141. The fourth electrode 147 is at the ground potential.

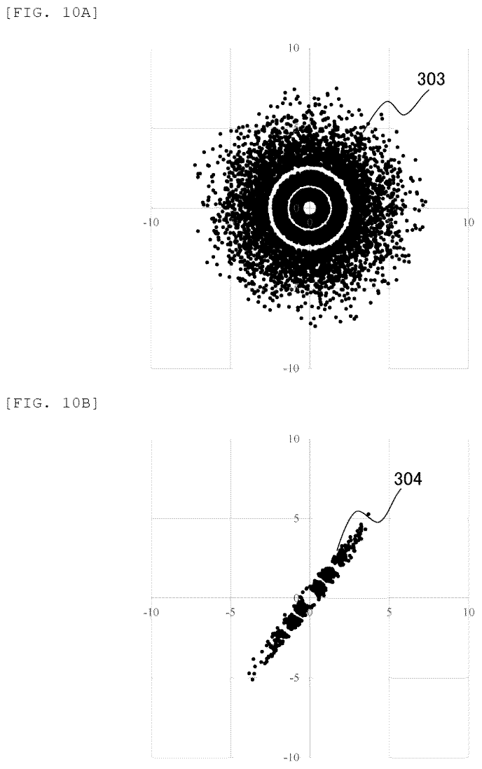

FIGS. 9A and 9B show behaviors of secondary electrons, reflected electrons, and tertiary electrons in a case where a segmented electrode 141a close to the center is set to the ground potential and a positive voltage is applied to a segmented electrode 141b far from the center.

The tertiary electron 123 emitted from the segmented electrode 141a set to the ground potential is directed to the detector 110. Meanwhile, a tertiary electron 148 emitted from the segmented electrode 141b to which the positive voltage is applied is pulled back to the segmented electrode 141b by an electric field between the segmented electrode 141b and the fourth electrode 147, and thus is not detected. By providing the fourth electrode 147, an effect is obtained that accuracy of secondary electron discrimination detection is improved since a retarding electric field experienced by the tertiary electron 148 emitted from the segmented electrode 141b to which the positive voltage is applied is strong and the tertiary electron 148 is not reliably detected.

In FIG. 9A, the third electrode 144 is set to the ground potential, and similarly to the first embodiment (FIG. 7A), the tertiary electron 161 emitted from the third electrode 144 passes through the second electrode 143 and further the first electrode 142, and reaches the detector 110, whereby accuracy of secondary electron discrimination decreases. In this regard, in FIG. 9B, a positive voltage of +30 V is applied to the third electrode 144 by the power supply 162. In this case, the tertiary electron 161 is pulled back to the third electrode 144 by the electric field between the second electrode 143 and the third electrode 144, and is not detected. Accordingly, the accuracy of secondary electron discrimination is improved.

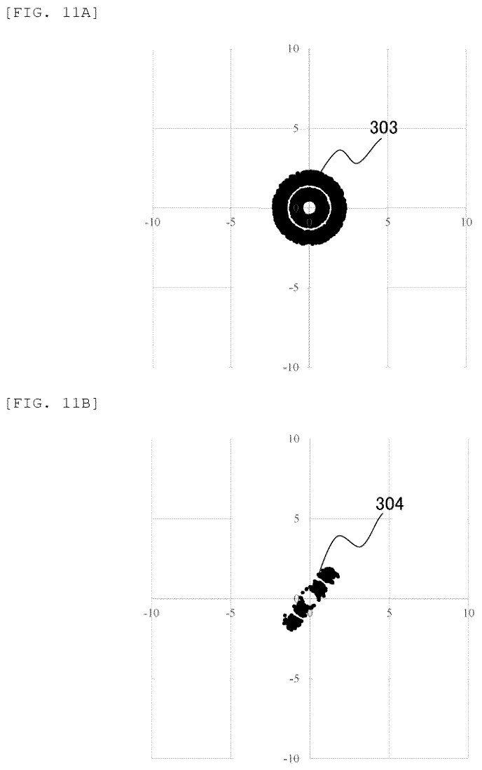

In the second embodiment, collision positions with the beam guide 146 and the electron conversion electrode 141 can still be obtained from an electron trajectory analysis result of the secondary electron emitted from the specimen. FIG. 10A shows collision positions 303 of secondary electrons with the beam guide and the electron conversion electrode when 10,000 secondary electrons are emitted from the trench top. The collision positions are divided into three areas and are concentrically distributed. From a center, there is an area of collision with the beam guide 146, an area of collision with the segmented electrode 141a, and an area of collision with the segmented electrode 141b. Meanwhile, FIG. 10B shows collision positions 304 of secondary electrons with the beam guide and the electron conversion electrode in a case where 10,000 secondary electrons are emitted from the trench bottom when an aspect ratio of the trench is 5. The collision positions are distributed in an elliptical shape, and a major axis direction of the ellipse is inclined by about 40° clockwise from the Y-axis. In this case, a distribution of the collision positions is segmented into three areas, that is, an area of collision with the beam guide 146, an area of collision with the segmented electrode 141a, and an area of collision with the segmented electrode 141b from a center.

Here, when the segmented electrode 141a, the segmented electrode 141b, and the beam guide are set to the ground potential, almost all secondary electrons are detected except for secondary electrons colliding with the separation groove. The number of secondary electrons from the trench top in FIG. 10A is about 7,800, and the number of secondary electrons from the trench bottom in FIG. 10B is about 600. Therefore, a BT ratio is about 0.08.

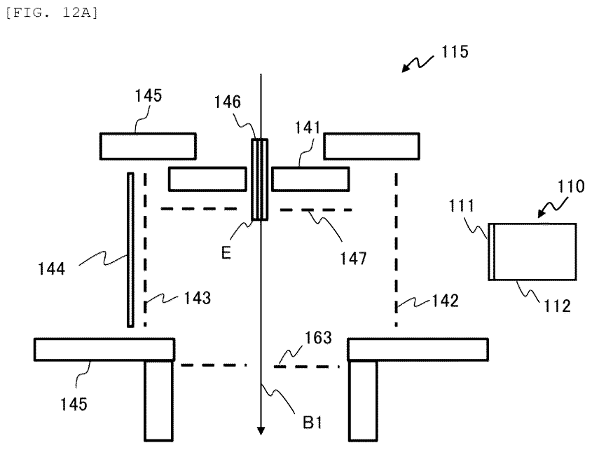

In contrast, when a positive voltage of +50 V is applied to the segmented electrode 141b and a positive voltage of +30 V is applied to the third electrode 144, secondary electrons colliding with the beam guide 146 or the segmented electrode 141a are detected. FIGS. 11A and 11B show collision positions of secondary electrons with the beam guide and the segmented electrode 141a extracted from FIGS. 10A and 10B, respectively. The number of secondary electrons from the trench top is about 3,000 when counted, and the number of secondary electrons from the trench bottom is about 440 when counted. Therefore, the BT ratio is about 0.15. That is, the BT ratio can be improved by about twice by segmenting the electron conversion electrode 141 into two, applying a positive voltage to the outer segmented electrode 141b, and applying a positive voltage to the third electrode 144.

### Third Embodiment

In the third embodiment, an example is shown in which the electron conversion electrode 141 is not segmented and the beam guide 146 (pipe electrode) is provided at the center of the electron conversion electrode 141. In the first and second embodiments, examples are shown in which the Wien filter is used to direct the tertiary electron to the detector, and alternatively, an electron deflector may be used. In the third embodiment, an example in which the electron deflector is used instead of the Wien filter is shown. When the electron deflector is used, the primary electron beam B1 is also deflected, and the deflection of the primary electron beam B1 by the electron deflector can be corrected by deflecting back by a subsequent deflector. Configurations and functions similar to configurations and functions described in the first and second embodiments are denoted by the same reference numerals, and description thereof is omitted.

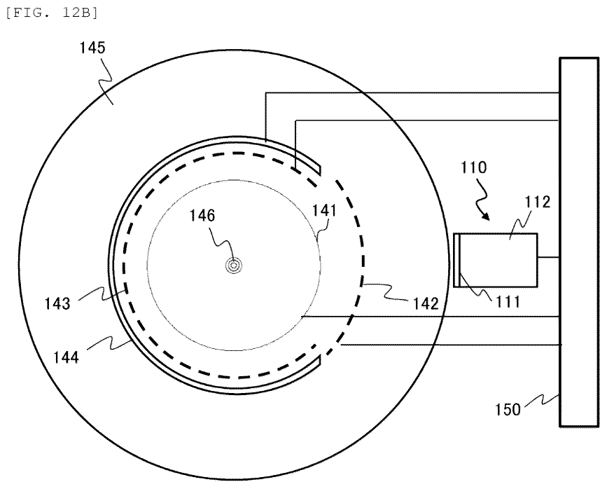

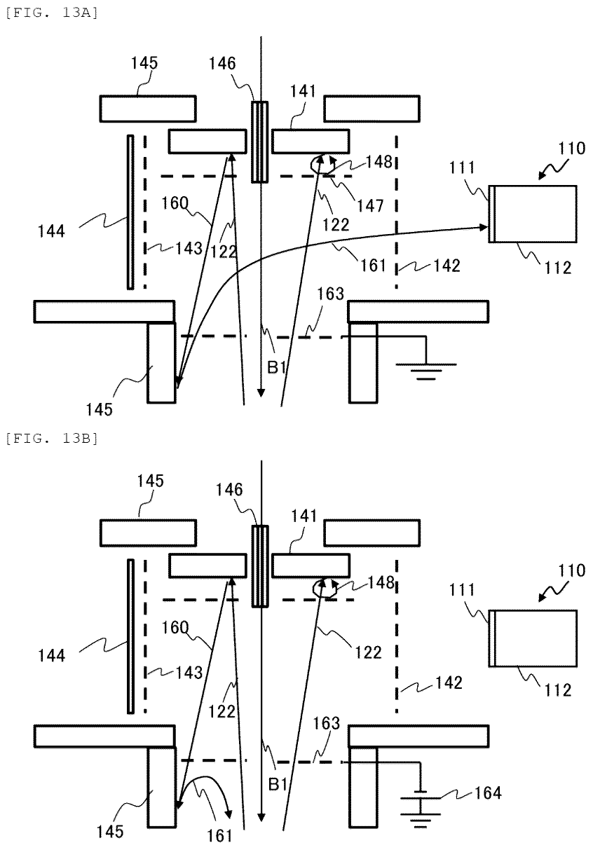

A detailed structure of an electron deflector 115 according to the third embodiment will be described with reference to FIGS. 12A and 12B. The electron deflector 115 deflects an electron only by an electric field without using any magnetic field. The Wien filter described in the first and second embodiments may also be considered as a type of the electron deflector. FIG. 12A is a cross-sectional view from beside, and FIG. 12B is a cross-sectional view in a planar direction. The electron conversion electrode 141 with which the secondary electron 122 collides is provided at an upper portion of the electron deflector 115. In the present embodiment, as shown in FIG. 12B, a power supply is connected to the unsegmented electron conversion electrode 141 to enable application of a positive or negative voltage, and independent switching between positive voltage application and negative voltage application or the ground potential is enabled. The beam guide 146 that is a hollow pipe electrode is provided at the center of the electron conversion electrode 141, and the primary electron beam B1 passes therethrough. The beam guide 146 and the electron conversion electrode 141 are electrically insulated by a concentric separation groove. By setting the beam guide 146 to the ground potential, a tertiary electron is also emitted from the end surface E of the beam guide 146. That is, the beam guide also serves as an electron conversion electrode. Accordingly, even though the electron conversion electrode 141 is not segmented, it can be said that there are substantially a plurality of electron conversion electrodes by providing both the electron conversion electrode 141 and the beam guide 146.

In addition to the first electrode 142, the second electrode 143, and the third electrode 144 similar to those in the first embodiment, the fourth electrode 147 similar to that in the second embodiment is provided at the electron deflector 115 in the present embodiment. Further, in the present embodiment, a fifth electrode 163 provided on the specimen side relative to the first electrode 142 and the second electrode 143 is provided. The fifth electrode 163 is an electrode that allows transmission of a secondary electron emitted from the specimen, such as a grid electrode or a mesh electrode.

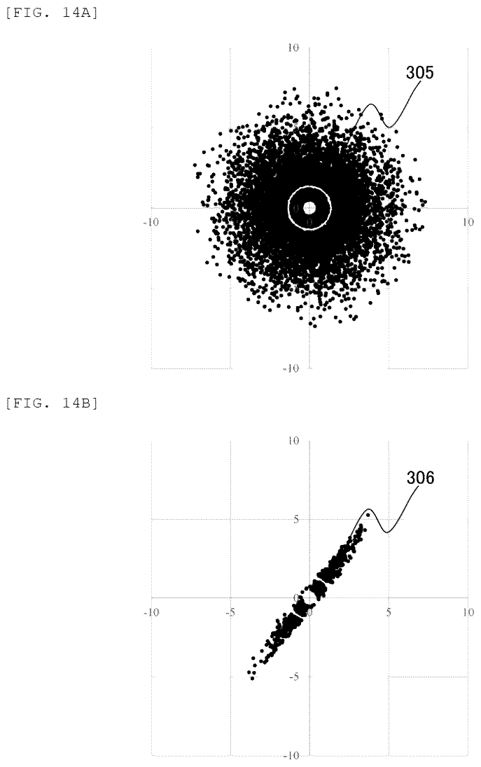

When observing the trench bottom, a positive voltage of 50 V is applied to the electron conversion electrode 141. FIGS. 13A and 13B show behaviors of secondary electrons, reflected electrons, and tertiary electrons when a positive voltage is applied to the electron conversion electrode 141 and the beam guide 146 is at a ground voltage. In this case, the tertiary electron 148 emitted from the electron conversion electrode 141 is pulled back to the electron conversion electrode 141 due to a potential difference between the electron conversion electrode 141 and the fourth electrode 147 set to the ground potential, and thus is not detected. An effect is obtained that a retarding electric field experienced by the tertiary electron due to the fourth electrode 147 is strong, the tertiary electron is not reliably detected, and accuracy of secondary electron discrimination detection is improved. In this regard, the tertiary electron emitted from the end surface of the beam guide 146 at the ground potential is detected.

Next, a function of the fifth electrode 163 will be described. In FIG. 13A, the fifth electrode 163 is set to the ground potential. In this case, the tertiary electron 161, which is generated when the electron 160 obtained by reflecting the secondary electron 122 by the electron conversion electrode 141 collides with an inner wall of the housing 145, passes through the fifth electrode 163 and is detected. Accordingly, the secondary electron colliding with the electron conversion electrode 141 to which the positive voltage is applied is detected as a result, and accuracy of secondary electron discrimination decreases.

In contrast, in FIG. 13B, a negative voltage of −30 V is applied to the fifth electrode 163 by a power supply 164. In this case, the tertiary electron 161 generated by collision, with the housing 145, of the electron 160 obtained by reflecting the secondary electron 122 by the electron conversion electrode 141 is pulled back downward by an electric field between the fifth electrode 163 and the housing 145, and is not detected by the detector 110. That is, since the secondary electron colliding with the electron conversion electrode 141 to which the positive voltage is applied is not detected, the accuracy of secondary electron discrimination is improved as compared to the case of FIG. 13A.

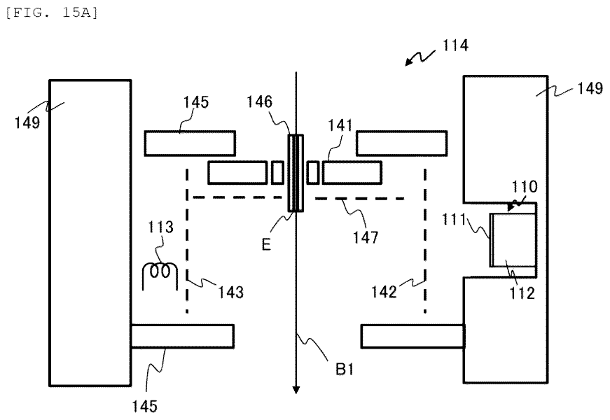

In the third embodiment, collision positions with the beam guide 146 and the electron conversion electrode 141 can still be obtained from an electron trajectory analysis result of the secondary electron emitted from the specimen. FIG. 14A shows collision positions 305 of secondary electrons with the beam guide and the electron conversion electrode when 10,000 secondary electrons are emitted from the trench top. The collision positions are concentrically distributed, and a distribution of the collision positions is divided into two areas. From a center, there is an area of collision with the beam guide 146 and an area of collision with the electron conversion electrode 141. Meanwhile, FIG. 14B shows collision positions 306 of secondary electrons with the beam guide and the electron conversion electrode in a case where 10,000 secondary electrons are emitted from the trench bottom when an aspect ratio of the trench is 5. The collision positions are distributed in an elliptical shape, and a major axis direction of the ellipse is inclined by about 40° clockwise from the Y-axis. In this case, a distribution of the collision positions is divided into two areas, that is, an area of collision with the beam guide 146 and an area of collision with the electron conversion electrode 141 from a center.

Here, when the electron conversion electrode 141 and the beam guide 146 are set to the ground potential, almost all secondary electrons are detected except for secondary electrons colliding with the separation groove. The number of secondary electrons from the trench top in FIG. 14A is about 9,000, and the number of secondary electrons from the trench bottom in FIG. 14B is about 700. Therefore, a BT ratio is about 0.08.

In contrast, when a positive voltage of +50 V is applied to the electron conversion electrode 141 and a positive voltage is applied to the third electrode 144 such that secondary electrons colliding with the electron conversion electrode 141 are not detected, the number of secondary electrons emitted from the trench top and colliding with the beam guide is about 1,400, and the number of secondary electrons emitted from the trench bottom and colliding with the beam guide is about 250. Therefore, the BT ratio is about 0.18. That is, the BT ratio can be improved by about twice by applying a positive voltage without segmenting the electron conversion electrode 141 and applying a positive voltage to the third electrode 144.

The voltage applied to the fifth electrode 163 is preferably switchable between negative voltage application and the ground potential. As described above, when a negative voltage is applied to the fifth electrode 163, the visibility of the trench bottom can be improved. Conversely, when the fifth electrode 163 is set to the ground potential, a bright image can be obtained for an observed target having little unevenness. In this regard, a negative voltage may be constantly applied to the fifth electrode 163. In this case, although the specimen surface is slightly darkened in observation, since a power supply or a switching system is not necessary, a low cost apparatus can be provided.

### Fourth Embodiment

A fourth embodiment shows an example in which the electron conversion electrode 141 is radially segmented into eight and concentrically into two, that is, the electron conversion electrode 141 is segmented into sixteen. In addition, an example is shown in which an electron deflector (Wien filter) is implemented by regarding an electron microscope casing as the third electrode. In the fourth embodiment, configurations and functions similar to configurations and functions described in the first to third embodiments are denoted by the same reference numerals, and description thereof is omitted.

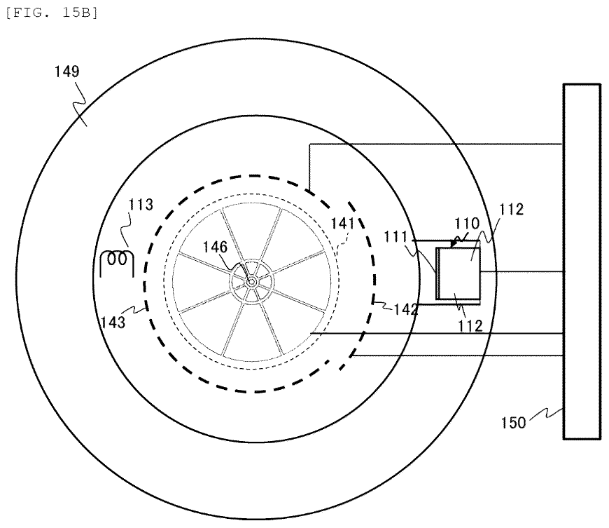

A detailed structure of the Wien filter 114 in the fourth embodiment will be described with reference to FIGS. 15A and 15B. FIG. 15A is a cross-sectional view from beside, and FIG. 15B is a cross-sectional view in a planar direction. The electron conversion electrode 141 with which the secondary electron 122 collides is provided at the upper portion of the Wien filter 114. In the present embodiment, as shown in FIG. 15B, the electron conversion electrode 141 is radially segmented into eight, concentrically segmented into two, which is a total of sixteen. A power supply is connected to each of the sixteen segmented electrodes such that a positive voltage or a negative voltage can be applied, and independent switching between positive voltage application and negative voltage application or the ground potential is enabled. The beam guide 146 that is a hollow pipe electrode is provided at the center of the electron conversion electrode 141, and the primary electron beam B1 passes therethrough. The beam guide 146 and the electron conversion electrode 141 are also electrically insulated by a concentric separation groove.

The Wien filter 114 in the present embodiment is provided with the first electrode 142 and the second electrode 143, and further, an electron microscope casing 149 serves as the third electrode 144 in the first to third embodiments.

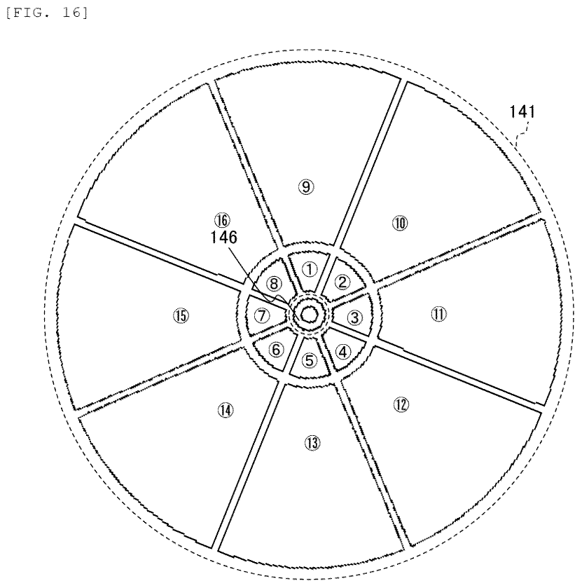

FIG. 16 shows a detailed structure of the beam guide 146 and the electron conversion electrode 141. The electron conversion electrode 141 is segmented into sixteen. An inner side of the electron conversion electrode 141 is segmented into segmented electrodes 1 to 8, whereas an outer side is segmented into segmented electrodes 9 to 16. A power supply is connected to each segmented electrode, and the control apparatus 150 independently controls switching between positive voltage application and negative voltage application or the ground potential.

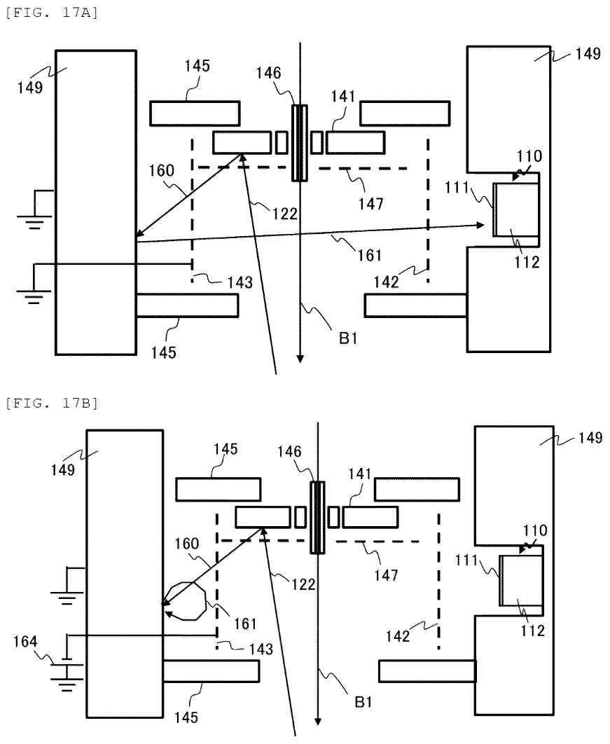

FIG. 17A shows behaviors of a secondary electron, a reflected electron, and a tertiary electron when the segmented electrodes 2 and 6 of the electron conversion electrode 141 are set to the ground potential, a positive voltage is applied to the other fourteen segmented electrodes, and the second electrode 143 is set to the ground potential. In this way, the electron conversion electrode is radially segmented, the segmented electrodes facing each other are made to have substantially the same potential, and thus an azimuth angle suitable for observing the trench bottom can be discriminated. In particular, voltage control can be simplified.

When the electron conversion electrode 141 is radially segmented and different voltages are applied to the segmented electrodes as in the present embodiment, an effect of preventing distortion of the primary electron beam B1 by the beam guide 146 is particularly important. The voltage application to the electron conversion electrode 141 can prevent the distortion of the primary electron beam B1 and deterioration of observation resolution of the scanning electron microscope. Therefore, it is desirable that the specimen-side end surface E of the beam guide 146 is at the same position as the fourth electrode 147 or is closer to the specimen than the fourth electrode 147.

In FIG. 17A, since the second electrode 143 is at the ground potential, the tertiary electron 161 generated when an electron obtained by reflecting the secondary electron 122 by the electron conversion electrode 141 collides with an inner wall of the electron microscope casing 149 passes through the second electrode 143 and is detected. In this way, since the secondary electron colliding with the segmented electrode of the electron conversion electrode 141 to which the positive voltage is applied is detected as a result, accuracy of secondary electron discrimination deteriorates.

In contrast, FIG. 17B shows behaviors of a secondary electron, a reflected electron, and a tertiary electron in a case where a negative voltage of −30 V is applied to the second electrode 143 by the power supply 164 from FIG. 17A. In this case, the tertiary electron 161 generated by collision of the electron 160 obtained by reflecting the secondary electron 122 by the electron conversion electrode 141 with the inner wall of the electron microscope casing 149 is pulled back to the electron microscope casing 149 by an electric field between the second electrode 143 and the electron microscope casing 149, and is not detected by the detector 110. That is, since the secondary electron colliding with the segmented electrode of the electron conversion electrode 141 to which the positive voltage is applied is not detected, the accuracy of secondary electron discrimination is improved.

In the fourth embodiment, the azimuth angle discrimination in the first embodiment and the elevation angle discrimination in the second embodiment can be performed in a hybrid manner. Therefore, it is possible to further increase the BT ratio.

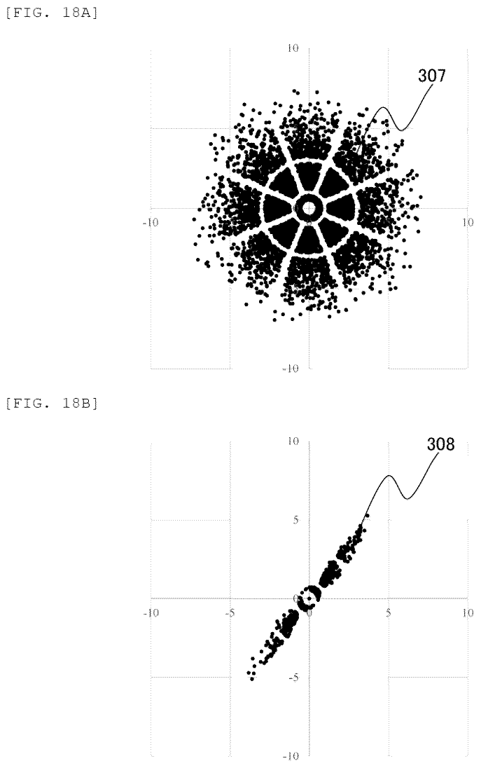

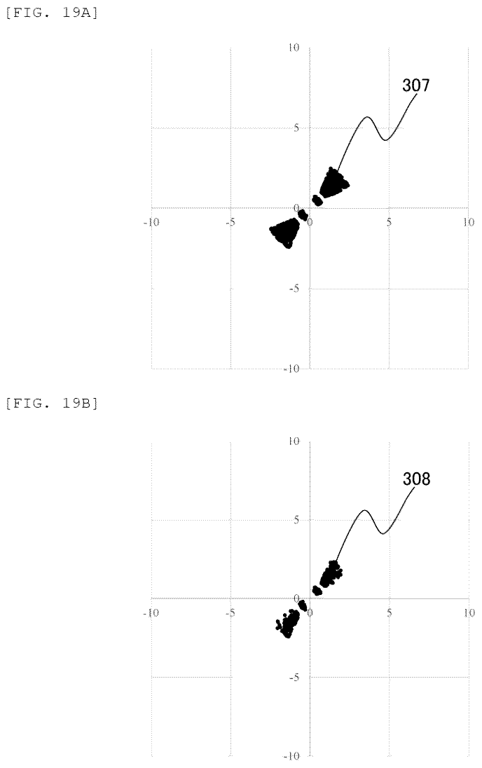

In the fourth embodiment, collision positions with the beam guide 146 and the electron conversion electrode 141 can still be obtained from an electron trajectory analysis result of the secondary electron emitted from the specimen. FIG. 18A shows collision positions 307 of secondary electrons with the beam guide and the electron conversion electrode when 10,000 secondary electrons are emitted from the trench top. The collision positions are concentrically distributed, and a distribution of the collision positions is divided into seventeen areas. From a center, there is an area of collision with the beam guide 146 and areas of collision with the segmented electrodes 1 to 16. Meanwhile, FIG. 18B shows collision positions 308 of secondary electrons with the beam guide and the electron conversion electrode in a case where 10,000 secondary electrons are emitted from the trench bottom when an aspect ratio of the trench is 5. The collision positions are distributed in an elliptical shape, and a major axis direction of the ellipse is inclined by about 40° clockwise from the Y-axis. In this case, a distribution of the collision positions is segmented into five areas, that is, an area of collision with the beam guide 146, areas of collision with the segmented electrodes 2 and 6, and areas of collision with the segmented electrodes 10 and 14 from a center.

Here, when all the segmented electrodes and the beam guide are set to the ground potential, almost all secondary electrons are detected except for secondary electrons colliding with the separation groove. The number of secondary electrons from the trench top in FIG. 18A is about 6,000, and the number of secondary electrons from the trench bottom in FIG. 18B is about 500. Therefore, the BT ratio is about 0.08.

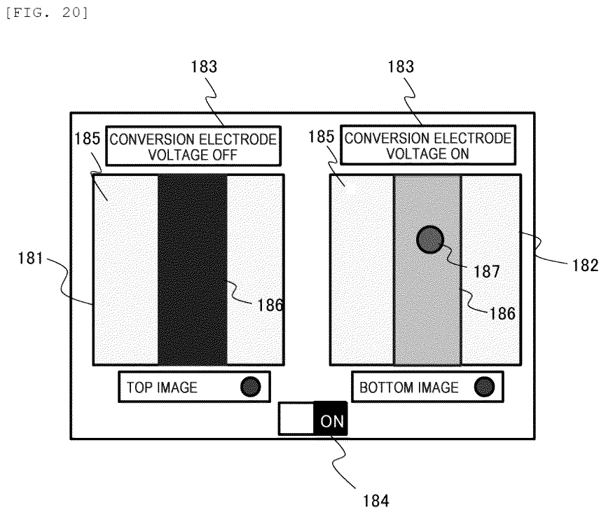

In contrast, when the segmented electrodes 2 and 6 of the electron conversion electrode 141 are set to the ground potential and a positive voltage of +50 V is applied to the segmented electrodes other than the segmented electrodes 2 and 6, the secondary electrons colliding with the beam guide 146 or the segmented electrodes 2 and 6 are detected. FIGS. 19A and 19B show collision positions of secondary electrons with the beam guide and the segmented electrodes 2 and 6 extracted from FIGS. 18A and 18B, respectively. The number of secondary electrons from the trench top is about 800 when counted, and the number of secondary electrons from the trench bottom is about 350 when counted. Therefore, the BT ratio is about 0.44. Here, by applying a negative voltage to the second electrode 143 so as not to detect a tertiary electron generated at the electron microscope casing 149, a high BT ratio close to the ideal value can be obtained. As compared to the case of FIG. 18A, the BT ratio is improved by about five times.

The voltage applied to the second electrode 143 is preferably switchable between negative voltage application and the ground potential. As described above, when a negative voltage is applied to the second electrode 143, the visibility of the trench bottom can be improved. Conversely, when the second electrode 143 is set to the ground potential, a bright image can be obtained for an observed target having little unevenness.

Finally, an example of a screen displayed on the display 151 of the scanning electron microscope will be described with reference to FIG. 20. On the screen shown in FIG. 20, a secondary electron image 181 when all electron conversion electrodes are at the ground potential, a secondary electron image 182 when a positive voltage is applied to a part or all of the electron conversion electrodes as shown in the first to fourth embodiments, an indicator 183, an electron conversion electrode voltage switch 184, and the like are displayed. At this time, as shown in each embodiment, it is desirable to control voltages applied to the second electrode 143 (fourth embodiment), the third electrode 144 (first to third embodiments), and the fifth electrode 163 (third embodiment) according to positive voltage application to the electron conversion electrode.

Both the secondary electron image 181 and the secondary electron image 182 are images generated based on a detection signal transmitted from the detector 110. In this case, the secondary electron image 182 when a positive voltage is applied to the electron conversion electrode while the electron conversion electrode voltage switch 184 is ON is a real-time image. Meanwhile, as the secondary electron image 181, an image acquired and stored in the past is displayed.

In the secondary electron image 181, a trench top 185 is observed bright, and a trench bottom 186 is completely dark and is not observed. Meanwhile, in the secondary electron image 182, since the trench top 185 is relatively dark, the trench bottom 186 is observed bright. Therefore, foreign matter 187 at the trench bottom can be visually recognized. The secondary electron image 181 is an image suitable for observing the trench top, and the secondary electron image 182 is an image suitable for observing the trench bottom. Depending on an observation purpose, images may be switched for observation. A specimen structure can be better understood by observing the two images through comparison in this manner.

A plurality of embodiments of the electron microscope of the invention have been described above. The invention is not limited to the above embodiments, and can be embodied by modifying components in a range not departing from the gist of the invention. A plurality of components disclosed in the above embodiments can be appropriately combined as long as there is no contradiction in the combination. Further, some components can be deleted from all the components shown in the above embodiments.

### Reference Signs List

100 . . . electron microscope

101 . . . electron gun

102 . . . extraction electrode

104 . . . anode

105 . . . focusing lens

106 . . . aperture

107 . . . adjustment knob

108 . . . upper deflector

109 . . . lower deflector

110 . . . detector

111 . . . fluorescent plate

112 . . . photomultiplier tube

113 . . . coil

114 . . . Wien filter

115 . . . electron deflector

116 . . . magnetic pole

117 . . . objective lens coil

118 . . . objective lens

120 . . . specimen

121 . . . specimen stage

122 . . . secondary electron

123 . . . tertiary electron

124 . . . power supply

133 . . . magnetic field

134 . . . electric field

141 . . . electron conversion electrode

142 . . . first electrode

143 . . . second electrode

144 . . . third electrode

145 . . . housing

146 . . . beam guide

147 . . . fourth electrode

148 . . . tertiary electron

149 . . . electron microscope casing

150 . . . control apparatus

151 . . . display

152 . . . storage apparatus

153 . . . control table

160 . . . reflected electron

161 . . . tertiary electron

162 . . . power supply

163 . . . fifth electrode

164 . . . power supply

181, 182 . . . secondary electron image

183 . . . indicator

184 . . . electron conversion electrode voltage switch

185 . . . trench top

186 . . . trench bottom

187 . . . foreign matter

200 . . . trench

201 . . . secondary electron emission vector

202 . . . elevation angle

203 . . . azimuth angle

204 . . . trench bottom

205 . . . trench top

210, 211 . . . secondary electron

301, 302, 303, 304, 305, 306, 307, 308 . . . collision position

1. A scanning electron microscope, comprising:
an electron source;
an objective lens configured to focus a primary electron beam emitted from the electron source on a specimen;
a deflector configured to deflect, using at least an electric field, an electron between the electron source and the objective lens;
a stage where the specimen is placed;
a power supply configured to apply, to the stage, a voltage for decelerating the primary electron beam;
a detector configured to detect an electron; and
a control apparatus, wherein
the deflector includes an electron conversion electrode provided to collide with a secondary electron emitted from the specimen due to emission of the primary electron beam, a first electrode and a second electrode facing each other and allowing transmission of an electron therethrough, and a third electrode facing the first electrode with the second electrode interposed therebetween,
the detector detects a tertiary electron that is emitted due to collision of the secondary electron emitted from the specimen with the electron conversion electrode and that is transmitted through the first electrode,
the electron conversion electrode is segmented into a plurality of segmented electrodes, and
the control apparatus causes a potential of the third electrode to have a positive potential difference relative to a potential of the second electrode.

2. The scanning electron microscope according to claim 1, wherein
the potential of the third electrode is switchable between a positive potential difference and a negative potential difference or an equal potential relative to the potential of the second electrode.

3. The scanning electron microscope according to claim 2, wherein
each of the plurality of segmented electrodes of the electron conversion electrode is independently switchable between positive voltage application and negative voltage application or a ground potential, and
when a positive voltage is applied to one or more of the segmented electrodes of the electron conversion electrode, the control apparatus switches the potential of the third electrode to the positive potential difference relative to the potential of the second electrode.

4. The scanning electron microscope according to claim 1, wherein
the deflector includes a beam guide that penetrates the electron conversion electrode and through which the primary electron beam passes, and
the electron conversion electrode and the beam guide are electrically insulated from each other.

5. The scanning electron microscope according to claim 4, wherein
the deflector includes a fourth electrode that faces the electron conversion electrode and that allows transmission of an electron therethrough, and
the fourth electrode is provided at a same height as a specimen-side end surface of the beam guide or closer to the electron conversion electrode.

6. The scanning electron microscope according to claim 1, wherein
the deflector includes a fifth electrode that is provided closer to the specimen than the first electrode and the second electrode and that allows transmission of an electron therethrough, and
the control apparatus applies a negative voltage to the fifth electrode.

7. The scanning electron microscope according to claim 1, wherein
the third electrode is an electron microscope casing, and
a negative voltage is applied to the second electrode in order to cause the potential of the third electrode to have a positive potential difference relative to the potential of the second electrode.

8. The scanning electron microscope according to claim 1, wherein
the plurality of segmented electrodes radially segment the electron conversion electrode.

9. The scanning electron microscope according to claim 8, wherein
among the plurality of segmented electrodes, electrodes facing each other have substantially a same potential.

10. The scanning electron microscope according to claim 1, wherein
the plurality of segmented electrodes concentrically segment the electron conversion electrode.

11. The scanning electron microscope according to claim 1, wherein
the deflector is a Wien filter including a coil that generates a magnetic field to deflect an electron.

12. A scanning electron microscope, comprising:
an electron source;
an objective lens configured to focus a primary electron beam emitted from the electron source on a specimen;
a deflector configured to deflect, using at least an electric field, an electron between the electron source and the objective lens;
a stage where the specimen is placed;
a power supply configured to apply, to the stage, a voltage for decelerating the primary electron beam;
a detector configured to detect an electron; and
a control apparatus, wherein
the deflector includes an electron conversion electrode provided to collide with a secondary electron emitted from the specimen due to emission of the primary electron beam, a beam guide that penetrates the electron conversion electrode and through which the primary electron beam passes, and a first electrode and a second electrode facing each other and allowing transmission of an electron therethrough,
the detector detects a tertiary electron that is emitted due to collision of the secondary electron emitted from the specimen with the electron conversion electrode or a specimen-side end surface of the beam guide and that is transmitted through the first electrode,
the electron conversion electrode is switchable independently between positive voltage application and negative voltage application or a ground potential,
the deflector includes a fourth electrode facing the electron conversion electrode and allowing transmission of an electron therethrough, and
the fourth electrode is set to the ground potential and is provided at a same height as the specimen-side end surface of the beam guide or closer to the electron conversion electrode.

13. A specimen observation method using a scanning electron microscope, wherein
the scanning electron microscope includes: an electron source; an objective lens configured to focus a primary electron beam emitted from the electron source on a specimen; a deflector configured to deflect, using at least an electric field, an electron between the electron source and the objective lens; a stage where the specimen is placed; a power supply configured to apply, to the stage, a voltage for decelerating the primary electron beam; a detector configured to detect an electron; and a control apparatus,
the deflector includes an electron conversion electrode provided to collide with a secondary electron emitted from the specimen due to emission of the primary electron beam, a first electrode and a second electrode facing each other and allowing transmission of an electron therethrough, and a third electrode facing the first electrode with the second electrode interposed therebetween,
the detector detects a tertiary electron that is emitted due to collision of the secondary electron emitted from the specimen with the electron conversion electrode and that is transmitted through the first electrode,
the electron conversion electrode is segmented into a plurality of segmented electrodes, and
the control apparatus causes a potential of the third electrode to have a positive potential difference relative to a potential of the second electrode.

14. The specimen observation method according to claim 13, wherein
the potential of the third electrode is switchable between a positive potential difference and a negative potential difference or an equal potential relative to the potential of the second electrode,
each of the plurality of segmented electrodes of the electron conversion electrode is independently switchable between positive voltage application and negative voltage application or a ground potential, and
when a positive voltage is applied to one or more of the segmented electrodes of the electron conversion electrode, the control apparatus switches the potential of the third electrode to the positive potential difference relative to the potential of the second electrode.

15. The specimen observation method according to claim 13, wherein
the plurality of segmented electrodes radially or concentrically segment the electron conversion electrode.
